(19) United States
(12) Patent Application Publication
(10) Pub. No.: US 2015/0243617 A1
(43) Pub. Date: Aug. 27, 2015

(54) Method for Flip-Chip Bonding Using Copper Pillars

(71) Applicant: LSI Corporation, San Jose, CA (US)

(72) Inventors: John W. Osenbach, Kutztown, PA (US); Suzanne M. Emerich, Mertztown, PA (US); David Crouthamel, Bethlehem, PA (US); Steven D. Cate, Los Altos, CA (US)

(73) Assignee: LSI Corporation, San Jose, CA (US)

(21) Appl. No.: 14/190,659

(22) Filed: Feb. 26, 2014

(51) Int. Cl. H01L 23/00; H01L 21/54; H01L 23/34

(52) U.S. Cl. CPC H01L 24/13; H01L 24/05; H01L 24/03; H01L 24/11; H01L 24/81; H01L 23/34; H01L 21/54; H01L 2224/81801; H01L 2224/13147; H01L 2924/01029

(57) ABSTRACT

A bonding pad arrangement and method of bonding a flip-chip semiconductor device to a substrate using copper pillars and solder to join die pads on the flip-chip to substrate pads on the substrate. Each substrate pad has an offset from a respective die pad at specific temperature, the offset for each of the substrate pads is substantially the same, and the offset is determined as a function of the size of the flip-chip device, a difference between a solidification temperature of the solder and the specific temperature, and a difference between a coefficient of thermal expansion of the flip-chip device and a coefficient of thermal expansion of the substrate. Alternatively, the offset for each of the substrate pads is the above-determined offset scaled as a function of a distance the respective die pad is from the centroid of the device.

### CROSS-REFERENCE TO RELATED APPLICATIONS

The subject matter of this application is related to U.S. patent application Ser. No. 14/190,582, filed concurrently herewith as attorney docket no. L13-1421US1, titled “Method for Flip-Chip Bonding Using Copper Pillars”, the teachings of which are incorporated herein by reference.

### BACKGROUND OF THE INVENTION

1. Field of the Invention

The present invention relates to semiconductor packaging technology generally and more specifically, to bonding of flip-chip devices to a substrate using copper pillars and solder.

2. Description of the Related Art

Copper pillars are a widely used technique for electrically interconnecting a flip-chip semiconductor device or “chip” to conductors on an organic-based substrate, such as a thin (less than one millimeter thick) glass-epoxy board, because copper pillar interconnects have superior geometric control, higher density, and electrical performance relative to solder bump interconnects. The copper pillars formed on the device's die pads connect to the substrate's substrate pads by using a solder layer between each pillar and the respective substrate pad to join the copper pillars to the substrate pads.

To bond a flip-chip device to a substrate, the device and substrate are brought together and heated until the solder formed (usually by plating) on the ends of the copper pillars melts and wets the substrate pads on the substrate, each pillar and solder combination forming a lone. Then the device-substrate combination is cooled down and the solder solidifies to bond the device to the substrate, forming a bonded device-substrate structure or “package”. However, because the coefficient of thermal expansion (CTE) for the flip-chip device is significantly different from that of the substrate, changes in the package temperature causes the position of the substrate pads to laterally shift relative to die pads. This shift is referred to as offset, the amount of misalignment between a die pad and the corresponding substrate pad. During bonding, the device and the substrate are cooled down from the temperature that the solder melts to the temperature the solder solidifies and then to room temperature. As the package cools, the amount of offset each joint is subject to changes depending on where the pillars are located on the device. For example, the offset might be zero at the center of the device and tens of microns for pillars on pads at the periphery of the device. The larger the offset, the less likely the joint between a die pad and a substrate pad will occur without defects, such as voided regions and cracks, in the solder due to insufficient solder volume between the substrate pad and the pillar. The tendency to void or crack is particularly prevalent in smaller volume solder joints such as those found with copper pillar interconnect. Differences in height between the die pad and the corresponding substrate pad due to warping of the substrate or other variations can further aggravate the formation of the solder voids and cracks. Temperature cycling of the package will tend to drive solder creep that can weaken marginal joints, leading to additional cracks. Voids and cracks essentially decrease the cross sectional area of the solder joint, this combined with the small area at the tip of the void/crack enhances the propensity for crack initiation and growth in the solder when exposed to temperature cycling and or other thermal mechanical stresses that a device experiences during testing, transportation, or operation. Moreover, the temperature cycling and other stresses can cause the cracks to eventually cause separation in the copper pillar and solder joint connecting, the die to the substrate, possibly resulting in a functional failure of the packaged device. Thus, it is desirable to find a process for device-substrate bonding using copper pillars that might result in fewer interconnection defects and, concomitantly, a more reliable bonded device-substrate package.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Described embodiments include a package comprising a flip-chip device, a plurality of copper pillars, a substrate, and a plurality of solder layers. The flip-chip device has a centroid and a plurality of die pads thereon. Each of the copper pillars is disposed on a respective die pad of the plurality of die pads. The substrate has a plurality of substrate pads thereon and each of the solder layers is disposed between a respective copper pillar and a respective substrate pad. Each substrate pad has an offset from a respective die pad at a specific temperature, the offset for each of the substrate pads of the is substantially the same, and the offset is determined as a function of the size of the flip-chip device, a difference between a solidification temperature of the solder and the specific temperature, and a difference between a coefficient of thermal expansion of the flip-chip device and a coefficient of thermal expansion of the substrate. Alternatively, the offset for each of the substrate pads is not substantially the same and instead the above-determined offset is scaled as a function of a distance the respective die pad is from the centroid of the device.

### BRIEF DESCRIPTION OF THE DRAWINGS

Other embodiments of the present invention will become more fully apparent from the following detailed description, the appended claims, and the accompanying drawings in which like reference numerals identify similar or identical elements. The drawings are not to scale.

FIG. 1 is a cross-section of a flip-chip device bonded to a substrate using copper pillars and solder in one embodiment of the invention;

FIG. 2 is a cross-section of the structure of FIG. 1 prior to bonding;

FIGS. 3-5 are cross-sections of the structure of FIG. 1 according to various embodiments of the invention;

FIG. 6 is a diagram illustrating variation of force with die-to-substrate height for a copper pillar with two different offsets;

FIG. 7 is a diagram of a layout of die pads and substrate pads superimposed on each other according to one embodiment of the invention;

FIG. 8 is a diagram of a layout of die pads and substrate pads superimposed on each other according to another embodiment of the invention; and

FIG. 9 is a flowchart illustrating an exemplary process for bonding a flip-chip device to a substrate according to one embodiment of the invention.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation”.

As used in this application, the word “exemplary” is used herein to mean serving, as an example, instance, or illustration. Any aspect or design described herein as “exemplary” is not necessarily to be construed as preferred or advantageous over other aspects or designs. Rather, use of the word exemplary is intended to present concepts in a concrete fashion.

It should be understood that the steps of the exemplary methods set forth herein are not necessarily required to be performed in the order described, and the order of the steps of such methods should be understood to be merely exemplary. Likewise, additional steps might be included in such methods, and certain steps might be omitted or combined, in methods consistent with various embodiments of the present invention.

Also for purposes of this description, the terms “couple”, “coupling”, “coupled”, “connect”, “connecting”, or “connected” refer to any manner known in the art or later developed in which energy is allowed to be transferred between two or more elements, and the interposition of one or more additional elements is contemplated, although not required. Conversely, the terms “directly coupled”, “directly connected”, etc., imply the absence of such additional elements.

The present invention will be described herein in the context of illustrative embodiments of a process to bond a flip-chip device to a substrate by joining die pads on the flip-chip device to substrate pads on the substrate using joints of copper pillars and solder. Each substrate pad has an offset from a respective die pad at a specific temperature and the offset is determined as a function of the size of the flip-chip device, a difference between a solidification temperature of the solder and the specific temperature, and a difference between a coefficient of thermal expansion of the flip-chip device and a coefficient of thermal expansion of the substrate. In one embodiment the offset for each of the substrate pads of the is substantially the same and, in another embodiment, the offset for each of the substrate pads is equal to the above-determined offset scaled as a function of a distance the respective die pad is from the centroid of the device.

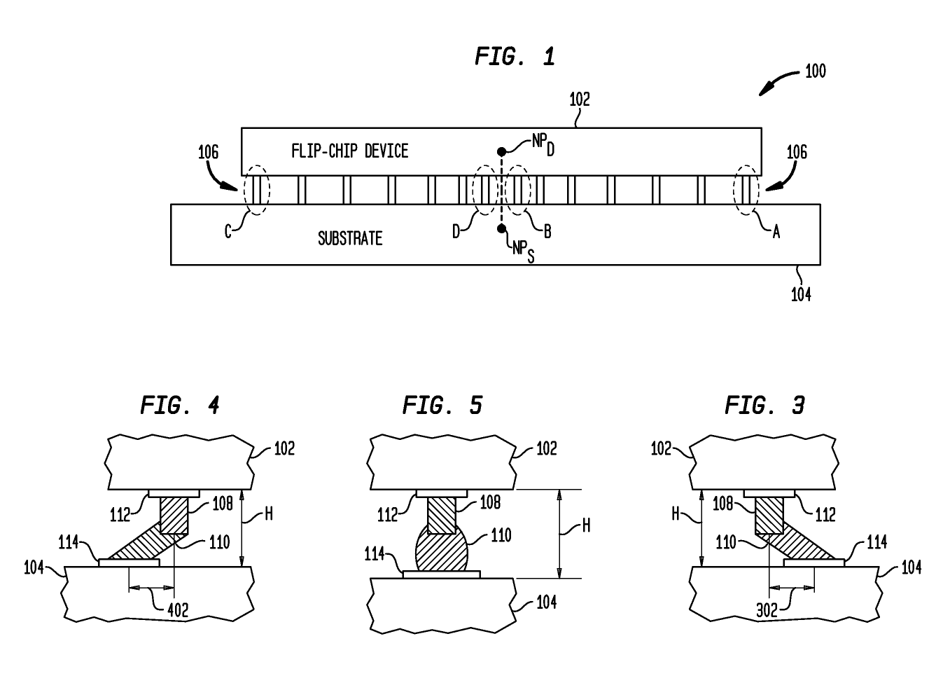

FIG. 1 is a cross-section of a flip-chip device 102 bonded to a substrate 104 to form a flip-chip package 100. Die pads (not shown) on the device 102 are bonded to substrate pads (not shown) on the substrate 104 using multiple conductors or joints 106. The device 102 might be formed from silicon, gallium arsenide, indium phosphide, or another semiconductor material suitable for the desired function of the device 102. The substrate 104 might be formed from a glass-epoxy (commonly known as FR-4), polytetrafluoroethylene (PTFE), polyimide, ceramics, silicon, glass, another insulating material suitable as a substrate, or a combination of these materials. Typically, the thickness of the substrate 104 is less than two millimeter and might be as thin as 50 microns (μm). The lateral dimensions of the substrate 104 are typically larger than that of the device 102. A neutral point on the device, NP_{D} and a neutral point on the substrate, NP_{S}, are shown aligned with each other to form a common neutral point referred to herein as the NP of the package 100. The neutral point NP_{D} is the centroid of the device 102 and is typically at the center of the device. Because the substrate might be asymmetrical, there might be multiple devices on a single substrate, or the device is not bonded to in the center of the substrate. NP_{S} is not necessarily the centroid of the substrate.

In this example, the joints 106 are arranged with a higher density near the center or NP_{D} of the device 102 than at the edges of the device. Generally, power and ground are supplied to the device 100 using the joints 106 at the center of the device 102 and high-speed signals are carried using the joints 106 at the edges of the device 102.

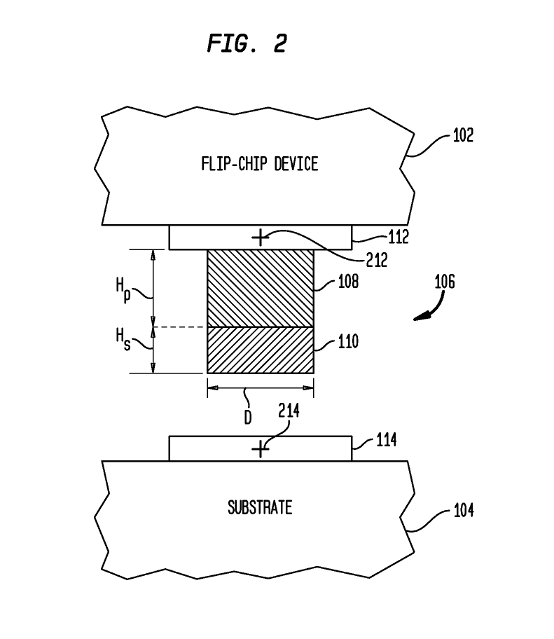

Referring to FIG. 2, one of the joints 106 in FIG. 1 is shown as the joint appears prior to bonding the device 102 to the substrate 104. The joint 106 is formed from a copper pillar 108 and a layer of solder 110. The copper pillar is formed on a die pad 112 that is typically made of copper. On substrate 104 is a respective one of the substrate pads 114, also typically made of copper, shown aligned with the die pad 112. The substrate copper pad might be coated with another metal such as tin, silver, a nickel-gold eutectic, or solder. In this example, the centroid 212 of the die pad 112 is aligned with the centroid 214 of the substrate pad 114. As will be shown in FIG. 1, the centroids might not be aligned due to alignment errors, intentional offsets between the respective die pads and substrate pads, and due a different coefficient of thermal expansion for the device 102 compared to that of the substrate 104. The coefficient of thermal expansion for the substrate is generally significantly larger than that of the device.

The copper pillar 108 has a height of H_{P} and the solder layer 110 has a height of H_{S} (before melting), and both have an approximate diameter D. The height of the joint is H_{P}÷H_{S}. In various embodiments, the height of the joint prior to melting ranges from 5 μm to 130 μm.

During the bonding process, the substrate 104 and device 102 are brought together so that the solder layer 110 contacts the respective substrate pad 114. The device and substrate are heated sufficiently for the solder 110 to melt, wetting both the substrate pad 114 and at least along part of the sides of the pillar 108 to form a joint. Then everything is cooled sufficiently for the solder 110 to solidify, thereby electrically and mechanically bonding the device 102 to the substrate 104.

FIG. 3 is a magnified view of the joint 106 from near the edge of the package 100 in circled area A of FIG. 1, the length or height of the completed joint, H, is the distance between the device 102 and the substrate 104. This view illustrates a joint 106 interconnecting a die pad 112 to a substrate pad 114 that is misaligned with the respective die pad. In this exaggerated view, the centroid (not shown) of the substrate pad 114 is substantially non-aligned with the centroid (not shown) of the die pad 112 by a distance referred to herein as offset. As a consequence of the misalignment, the re-solidified solder 110 is stretched between the pillar 108 and the substrate pad 114. One reason for the offset is that the coefficient of thermal expansion (CTE) for the flip-chip device 102 is significantly different from that of the substrate 104, and changes in the temperature of the package 100 causes the position of the substrate pads 114 to laterally shift relative to die pads 112. If the amount of offset is too large, the solder 110 might be insufficiently thick (in diameter) for the solder to sufficiently wet the substrate pad 114 and thus is susceptible to cracking as the temperature of the package 100 varies. The tendency to void or crack is particularly prevalent in smaller volume solder joints such as that found with copper pillar interconnects. Thus, the reliability of the device 100 might be undesirably compromised in packages having large offsets.

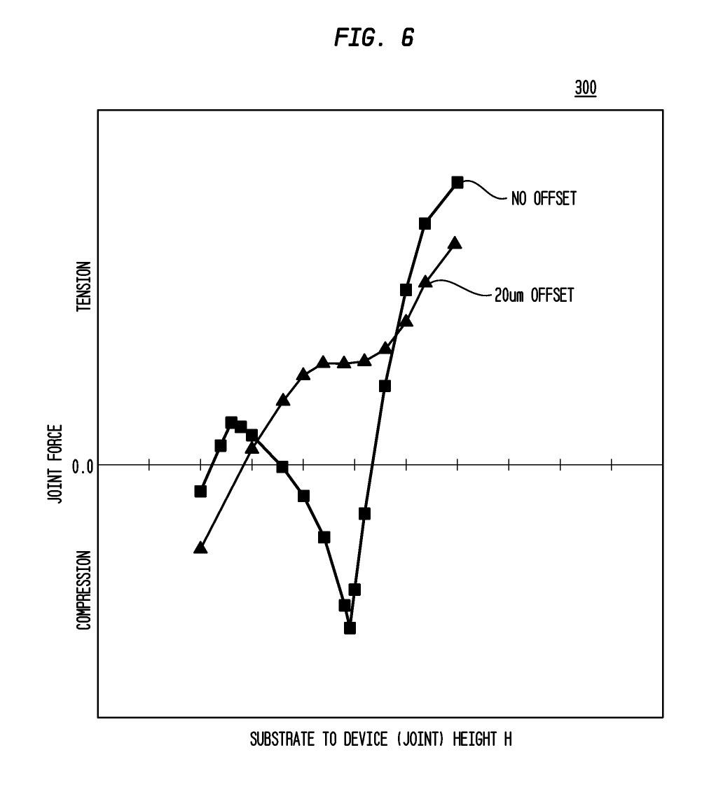

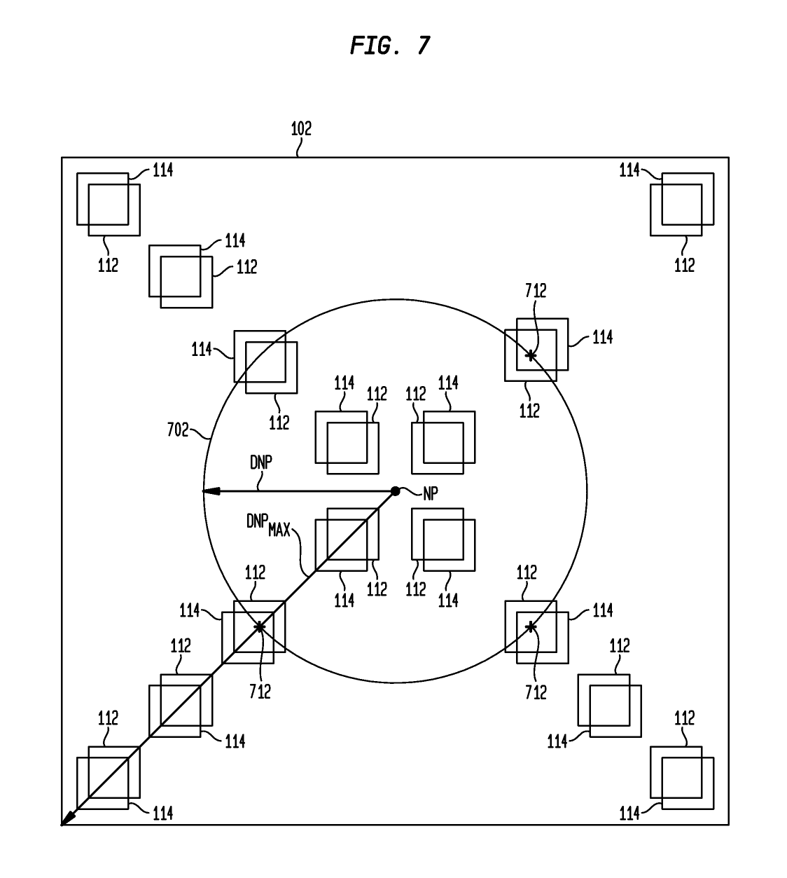

To address the above-described problem with large offsets, the combination of a copper pillar 108 and solder 110 between a die pad 112 and a substrate pad 114 has been modeled and the results are shown in FIG. 6. From the modeling, of the pillar 108 and the solder 110 in the liquid state, it is believed that the force (instantaneous energy-distance differential) that the joints 106 experiences varies significantly as the vertical distance between the device and the substrate, referred to above as joint height, H, changes. Further, variation in force vs. joint height of a single joint is significantly influenced by the amount of misalignment, or offset, of the die pad 112 and the substrate pad 114. This offset is caused by the difference in CTE of the die and substrate, and the elevated temperature of solder solidification. In the presence of offset, solder will tend to wet one side of the copper pillar 108, altering the force for a given joint height. In FIG. 6, the effect of the force vs. joint height curves for 102), cases are shown, first a no offset joint (typically for the joints 106 near the center of the device 102), and a joint with a 20 μm offset (typically for the joints 106 near the corner of the device 102). The amount of offset will generally vary linearly with distance from the center of the device 102. As shown, the joints with 20 μm of offset tend to be in tension for nearly all joint heights. However, for joints with no significant offset, there is a significant variation in joint force with different joint heights.

A flip-chip device 102 will have many tens to tens of thousands or more of joints 106. When considering the totality of all joints for a package 100, with the solder in the liquid state, the joints 106 are effectively captured between two rigid surfaces one being the die pads 112 and the other being the substrate pads 114. Force equilibrium requires that the sum of the forces over all of the joints equal the weight of the die, which can be approximated as zero for the case where there are many joints. Further, with each joint having a distinct force-height response curve as determined, by its degree of offset, the equilibrium requirement of zero net force implies some joints will be in tension while other will be in compression.

As shown in FIG. 6, for a given height, a copper pillar joint with pronounced offset will tend to be in tension, while a joint with minimal offset will tend to be in compression. This trend holds over a wide range of practical joint height values. Considering a flip-chip assembly with liquid solder joints in force equilibrium, this implies that for conventional packages where the solder joints toward the center of the device 102 have low offset while joints at the edges will have large offsets, the solder joints near the center will be in compression, while those toward the edges/corners of the device will be in tension.

Due to heat transfer dynamics in a reflow chamber where the device 102 is bonded to the substrate 104, the solder in the joints along the outer regions of the device will tend to cool faster and solidify before the joints toward the center of the device. While not wishing to be held to a particular theory, it is believed that at the start of solidification, these outer joints will be in tension due to their higher degree of offset. Because solder solidification is accompanied by volumetric shrinkage, which will tend to increase the tension in the outer joints before they fully solidify, collapse of the outer joints (i.e., the reduction in joint height in response to their tensile forces) is prevented by the opposing compressive force of the joints towards the center of the device 102 for which the solder is still in the liquid state. In this scenario, the outer joints become starved of solder as they solidify and will tend to exhibit tearing or cracking in the solder.

Any warpage of the package 100 that occurs during the cooling/solder solidification process might aggravate the solder-starved nature of the outer joints, thus increasing the potential for cracking.

In accordance with one embodiment of the invention, a method of decreasing the tendency of the outer joints to exhibit solder cracking during solidification is to reduce the tensile forces in those joints.

As shown in FIG. 6, the variation in forces for the substrate pad that is offset from a respective die pad by a calculated amount, here 20 μm relative to the die pad, is significantly smaller than that for the perfectly aligned joints. In addition, the device (joint) heights H that result in joints under compression are at the left hand site of the graph. This indicates that if all the joints are offset by approximately the calculated amount, again approximately 20 μm, then the individual solder joints will tend to go toward the left hand side of the graph, i.e. joint heights in and around the tension/compression crossover. Thus, the joints will tend to self-regulate in such a way as to minimize height differences and thus minimize the probability of solder tear.

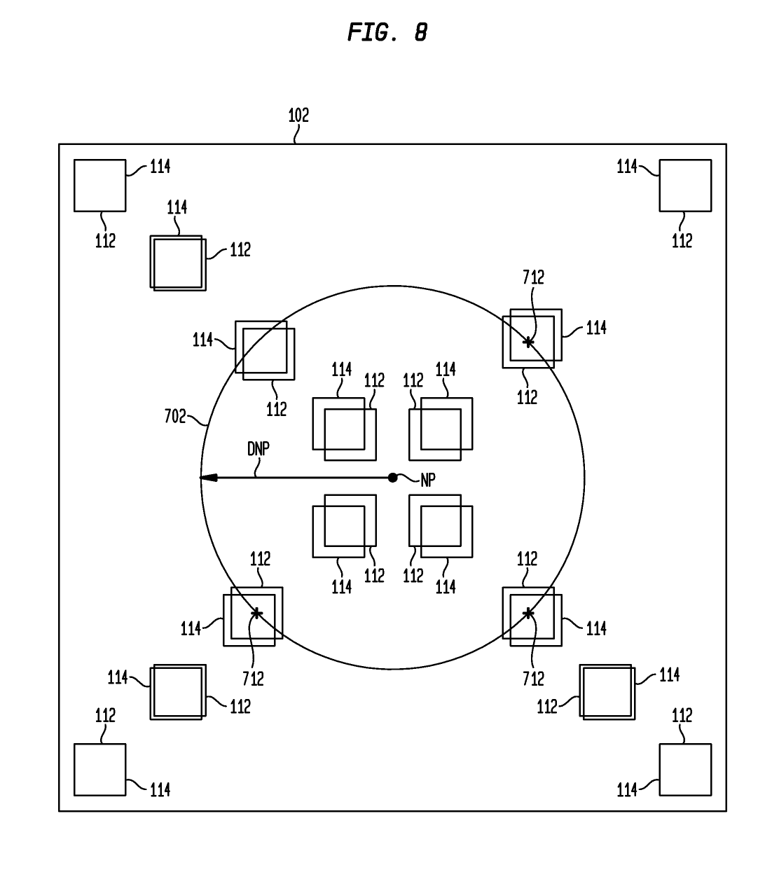

Recognizing this, the substrate pads positions are designed such that all of them have a calculated offset of an amount, such as 20 μm at a specific temperature such as room temperature (e.g., 25° C.) or the expected device operating temperature (e.g., 75° C.), although other offsets and temperatures could be used instead if they are found to provide acceptable joint shape. This is shown in FIG. 7. For illustrative purposes, the substrate pads 114 are shown being the same size as the die pads 112 although it is understood the pads might be of different size. The substrate pads 114 on substrate 104 are shown offset from the die pads 112 on flip-chip device 102 at room temperature. The device 102 and the substrate (not shown but extends beyond the boundary of flip-chip device 102) have a common neutral point NP, shown here as superimposed centroids of both the device and the substrate. Measured from the NP is a distance DNP, which is a radius of an imaginary circle 702, centered on the NP and passes through the centroids 712 of three different die pads. The maximum DNP, DNPₘₐₓ, is the largest radius of the imaginary circle centered on the NP or device centroid that overlays essentially all of the die pads on the flip-chip device 102 or substantially all of the flip-chip device as a whole. All of the substrate pads having similar offsets and displaced radially toward the outside of the flip-chip die, i.e., the centroids of the substrate pads 114 are displaced radially outward from the NP by the offset amount in relation to the respective centroids of the die pads. FIGS. 3 and 4 illustrate the effect of the offset on the positions of the joints 106 shown in FIG. 1. FIG. 3 presents a magnified view of the joint 106 from near the right edge of the package 100 in circled area A and, similarly, of the joint 106 right of center of the package 100 in the circled area B of FIG. 1. FIG. 3 illustrates a joint 106 interconnecting a die pad 112 to a substrate pad 114 that is misaligned with the die pad. In this exaggerated view, the centroid (not shown) of the substrate pad 114 is displaced from the centroid (not shown) of the die pad 112 by the offset distance 302 determined as discussed below. FIG. 4 presents a magnified view of the joint 106 from near the left edge of the package 100 in circled area C and, similarly, of the joint 106 near the left of center of the package 100 in the circled area D of FIG. 1. This view illustrates a joint 106 interconnecting a die pad 112 to a substrate pad 114 that is misaligned with the die pad. In this exaggerated view, the centroid (not shown) of the substrate pad 114 is also displaced from the centroid (not shown) of the die pad 112 by the offset distance 402. In one embodiment, the amount of the offsets 302, 402 is substantially the same but in opposite directions.

The amount of offset 302, 402 might be determined from a joint force diagram similar to that shown in FIG. 6 or from taking into consideration the difference in CTE between that of the substrate and that of the flip-chip die, and the difference between the solidification temperature and a specific temperature, such as room temperature. For example, the amount of offset at room temperature is:

Offset=DNPₘₐₓ×(CTE_{substrate}−CTE_{device})×(T_{solidification}−T) (Eqn. 1)
where: DNPₘₐₓ is the largest distance on the device from neutral point NP (device centroid);
   CTE_{substrate} and CTE_{device} are the CTE of the substrate and flip-chip device, respectively; and
   T_{solidification} and T are the solder solidification temperature and the specific temperature, respectively.

In one embodiment, the temperature T is an expected operating temperature of the device (e.g., 75° C.) and in another embodiment; T is room temperature (e.g., 25° C.).

In an alternative embodiment and as shown in FIG. 8, the offset for each pad is dependent on the distance the die pad is from the NP. In this embodiment, the substrate pad offset at room temperature is calculated by taking into account the difference in position of each die pad and respective substrate pad from the solidification temperature to room temperature as a result of CTE mismatch hi this embodiment, the offsets for each substrate pad is the offset calculated in Eqn. 1 (Offset), or from the graph in FIG. 6, scaled by the DNP of each pad in relation to the maximum distance, DNPₘₐₓ from Eqn. 1:

Offset_{pad}=Offset×(1−DNP_{pad}/DNPₘₐₓ) (Eqn. 2)
where: DNP_{pad} is the distance of the die pad from neutral point NP (device centroid).

As shown in FIG. 8, the substrate pads and die pads are substantially aligned (have no offset) at the corners of the device/substrate and gradually have increasing offset the closer the pads are to the NP, i.e., the smaller the DNP, the more the offset. It is understood that by using this technique where the pad offsets vary with DNP, all the die pads 112 and substrate pads 114 are unaligned when the device and substrate are heated to the solder solidification temperature (T_{solidification}) even though the edge/corner joints are substantially aligned at room temperature. As shown, each of the substrate pads 114 are offset outwardly from the respective die substrate pads 112. FIGS. 3-5 illustrate the effect of the changing offset on the positions of the joints 106 shown in FIG. 1 in accordance with this embodiment. FIG. 3 is a magnified view of the joint 106 from the right of center of the package 100 in circled area B and FIG. 4 is a magnified view of the joint 106 from near the left of center of the package 100 in circled area D in FIG. 1. The offset 302, 402 for these joints is substantially equal the full amount of offset, Offset. However, for the joints at outside edges in the circled areas A and C in FIG. 1, the amount of offset is close to zero as illustrated in FIG. 5. Here the substrate pad 114 is substantially aligned with the die pad 112.

### EXAMPLE

The CTE of Si is approximately 3 ppm/° C., the CTE of an organic substrate (e.g., FR-4) is approximately 13 ppm/° C. (this might range between 10 and 30 ppm/° C. for organic-base substrate and could be smaller, e.g., 5 to 10 ppm/° C. for certain low-CTE ceramic substrates). Here, assuming lead free solder with up to 50° C. undercooling, a solidification temperature (T_{solidification}) of 185° C. and a specified (e.g., room) temperature T of 25° C. In this case and from Eqn. 1, the amount of offset (Offset) is (13−3 ppm/° C.)×(185° C.−25° C.) or 0.16%. Assuming a 20 mm×20 mm device, DNPₘₐₓᵢₘᵤₘ (the distance from the center of device or NP to the farthest corner of the device) is 14.14 mm. Thus, from Eqn. 1, the maximum offset is 14.4 mm×0.16% or approximately 22.6 μm. In the embodiment shown in FIG. 4, all of the joints are offset by approximately 22.6 μm. Alternatively and as desired, a more practical offset of approximately 20 or 25 μm might be employed since this amount is more easily applied during design and has been found to be sufficient for a range of substrate CTEs.

In this embodiment, the copper pillars have a diameter of approximately 80 μm, a height H_{P} of 20-70 μm, and the solder layers, prior to melting, have a height H_{S} of 10-60 μm so that the total height is approximately 80 μm and might range from 5 μm to 130 μm. However, it is understood that the ratio of the height of the copper pillar to the height of the solder layer before melting can range from 1:10 to 100:1. The width of the substrate and die pads typically range from about 80% to about 120% of the diameter of the copper pillars.

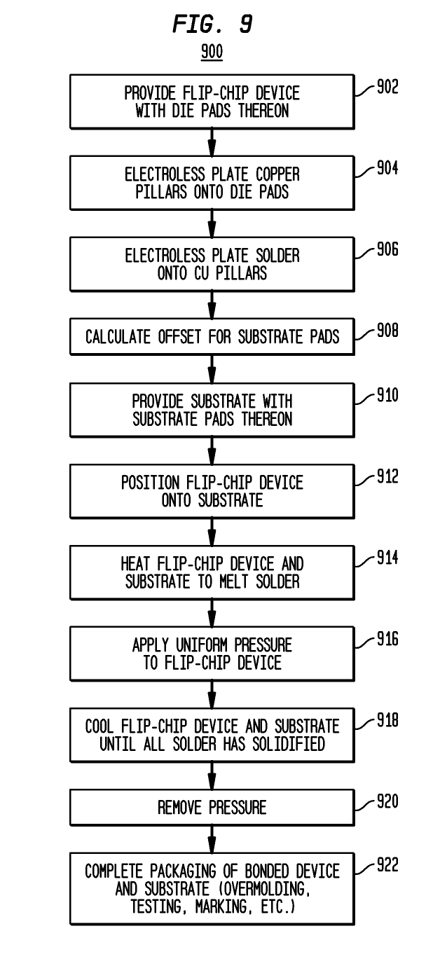

FIG. 9 is a simplified flowchart illustrating an exemplary process 900 for bonding a flip-chip device to a substrate. Starting with step 902, a flip-chip device is provided, such as device 102, that has die pads, such as die pads 112, thereon. Copper pillars, such as pillars 108, are fanned onto those die pads in step 904. In one embodiment, a masking material such as photoresist (not shown) is deposited onto the device, photoresist is then patterned to expose the die pads, and copper is plated onto the exposed die pads using, for example, a conventional electroless copper plating process to form the copper pillars. Next, in step 906, a layer of solder is plated onto the ends of the copper pillars. In one embodiment, a masking material such as photoresist (not shown) is deposited onto the device, the mask is then patterned to expose the ends of the copper pillars, and solder is plated onto the exposed die pads using, for example, a conventional solder electroless plating, process to form the solder layer. Once the die pad positions are known, then in step 908 offsets to apply to substrate pads on a later supplied substrate are determined by applying equations 1 or 2, discussed above. Then, in step 910, a substrate, such as substrate 104, is provided having substrate pads thereon. The substrate pads, such as substrate pads 114, are disposed on the substrate in substantially the same pattern as the pattern of the die pads on the flip-chip device but with offsets as determined in step 908. The flip-chip device and substrate are positioned in step 912 so that the copper pillars with the solder layers thereon are in contact with respective substrate pads. Then the flip-chip device, joints, and substrate are heated by, for example, the heater block, to melt the solder in the joints in step 914. Then, in step 916, the device and substrate are held in place by, for example, applying a small amount of uniform pressure to the flip-chip device using, for example, a piston. Next, in step 918, the heat is removed and the flip-chip device, joints, and substrate are allowed to cool until all the solder in the joints has solidified and the pressure, if any, is removed in step 920. Then the final steps to complete the packaging of the bonded device and substrate are done in step 922, such as forming an underfill layer between the device and the substrate, adding a heat spreader lid, forming an overmold of epoxy to device and substrate for environmental protection, testing, package marking, etc.

In an alternative embodiment, instead of applying the solder to the ends of the copper pillars, a solder layer is formed on the substrate pads 114 by using a patterned solder mask on the substrate 104 with the solder pads exposed and the solder plated onto the exposed pads, using either conventional electroplating or electroless plating.

Although the elements in the following method claims are recited in a particular sequence with corresponding labeling, unless the claim recitations otherwise imply a particular sequence for implementing some or all of those elements, those elements are not necessarily intended to be limited to being, implemented in that particular sequence.

It is understood that various changes in the details, materials, and arrangements of the parts which have been described and illustrated in order to explain the nature of this invention might be made by those skilled in the art without departing from the scope of the invention as expressed in the following claims.

1. A package comprising:
a flip-chip device having a centroid and a plurality of die pads thereon;
a plurality of copper pillars, each copper pillar disposed on a respective die pad of the plurality of die pads;
a substrate having a plurality of substrate pads thereon; and
a solder layer disposed between each one of the plurality of copper pillars and its respective substrate pad;
wherein each substrate pad has an offset from a respective die pad at specific temperature, the offset for each of the substrate pads of the is substantially the same, and the offset is determined as a function of the size of the flip-chip device, a difference between a solidification temperature of the solder and the specific temperature, and a difference between a coefficient of thermal expansion of the flip-chip device and a coefficient of thermal expansion of the substrate.

2. The package of claim 1 wherein the offset is determined in accordance with the following relationship;
offset=DNPₘₐₓ×(CTE_{substrate}−CTE_{device})×(T_{solidification}−T);
where: offset is the amount of offset between a substrate pad and its respective die pad;
DNPₘₐₓ is a farthest distance on the device from the device centroid;
CTE_{substrate} and CTE_{device} are the coefficients of expansion of the substrate and flip-chip device, respectively; and
T_{solidification} and T are the solder solidification and the specific temperatures, respectively.

3. The package of claim 1 wherein the specific temperature is one of a room temperature an expected operating temperature.

4. The package of claim 1 wherein the flip-chip device comprises a material selected from the group consisting of silicon, gallium arsenide, indium phosphide, and a combination thereof, and the substrate is selected from the group consisting of glass-epoxy, polytetrafluoroethylene, ceramic, silicon, glass, and a combination thereof.

5. The package of claim 1 further comprising an overmold over the flip-chip device and the substrate.

6. The package of claim 1 wherein the substrate has a centroid aligned with the centroid of the device.

7. A package comprising:
a flip-chip device having a centroid and a plurality of die pads thereon;
a plurality of copper pillars, each copper pillar disposed on a respective die pad of the plurality of die pads;
a substrate having a plurality of substrate pads thereon; and
a solder layer disposed between each one of the plurality of copper pillars and its respective substrate pad;
wherein each substrate pad has an offset from a respective die pad at specific temperature, the offset for each of the substrate pads of the is determined as a function of the size of the flip-chip device, a difference between a solidification temperature of the solder and the specific temperature, a difference between a coefficient of thermal expansion of the flip-chip device and a coefficient of thermal expansion of the substrate, and a distance the respective die pad is with respect to the centroid.

8. The package of claim 1 wherein the offset of each one of the plurality of substrate pads is determined in accordance with the following relationship:
offset=DNPₘₐₓ×(CTE_{substrate}−CTE_{device})×(T_{solidification}−T)×(1−DNP_{pad}/DNPₘₐₓ)
where: offset is the amount of offset between a substrate pad and its a respective die pad;
DNPₘₐₓ is a farthest distance on the device from the device centroid;
DNP_{pad} is a distance the die pad on the device is from the device centroid;
CTE_{substrate} and CTE_{device} are the coefficients of expansion of the substrate and flip-chip device, respectively; and
T_{solidification} and T are the solder solidification and the specific temperatures, respectively.

9. The package of claim 7 wherein the specific temperature is one of a room temperature or an expected operating temperature.

10. The package of claim 7 wherein the flip-chip device comprises a material selected from the group consisting of silicon, gallium arsenide, and indium phosphide, and the substrate is selected from the group consisting of glass-epoxy, polytetrafluoroethylene ceramic, silicon, glass, and a combination thereof.

11. The package of claim 7 further comprising an overmold over the flip-chip device and the substrate.

12. The package of claim 7 wherein the substrate has a centroid aligned with the centroid of the device.

13. A method comprising the steps of:
A) providing a flip-chip device having a centroid and a plurality of die pads thereon;
B) providing a plurality of copper pillars on respective die pads of the plurality of die pads;
C) forming a layer of solder on each of the copper pillars;
D) providing a substrate having a plurality of substrate pads, each of the plurality of substrate pads positioned on the substrate to align with a respective one of the copper pillars;
E) bringing the flip-chip device in proximity to the substrate until all the solder layers are in contact with respective substrate pads to form a device-substrate combination;
F) applying heat to the device-substrate combination to raise the temperature thereof until all of the solder melts; and
G) cooling the device-substrate combination to a temperature at which all of the solder solidifies;
wherein each substrate pad has an offset from a respective die pad at specific temperature, the offset for each of the substrate pads is substantially the same, and the offset is determined as a function of the size of the flip-chip device, a difference between a solidification temperature of the solder and the specific temperature, and a difference between a coefficient of thermal expansion of the flip-chip device and a coefficient of thermal expansion of the substrate.

14. The method of claim 13 wherein the offset is determined in accordance with the following relationship:
offset=DNPₘₐₓ×(CTE_{substrate}−CTE_{device})×(T_{solidification}−T);
where: offset is the amount of offset between a substrate pad and its respective die pad;
DNPₘₐₓ is a farthest distance on the device from the device centroid;
CTE_{substrate} and CTE_{device} are the coefficients of expansion of the substrate and flip-chip device, respectively; and
T_{solidification} and T are the solder solidification and the specific temperatures, respectively.

15. The method of claim 13 wherein each copper pillar has a height above a die pad and each of the solder layers has a height above a copper pillar, and a sum of the height of each copper pillar and its respective solder layer prior to step F) is between 5 microns and 130 microns.

16. The method of claim 15 wherein each copper pillar has a diameter of 80 microns or less and a sum of the height of each copper pillar and its respective solder layer prior to step is 80 microns or less.

17. The method of claim 13 wherein the flip-chip device comprises a material selected from the group consisting of silicon, gallium arsenide, indium phosphide, and a combination thereof, and the substrate is selected from the group consisting of glass-epoxy, polytetrafluoroethylene, ceramic, silicon, glass, a combination thereof, and a combination thereof.

18. The method of claim 13 further comprising the steps of:
H) forming, after step G), an underfill layer between the flip-chip device and the substrate.

19. The method of claim 18 further comprising the step of:
forming, after step H), an overmold on the flip-chip device and the substrate.

20. The method of claim 13 wherein the copper pillar is formed by the steps of:
depositing, a photoresist onto the flip-chip device;
patterning the photoresist to expose the plurality of die pads;
plating copper onto the exposed die pads; and
removing the photoresist.

21. A method comprising the steps of
A) providing a flip-chip device having a centroid and a plurality of die pads thereon;
B) providing a plurality of copper pillars on respective die pads of the plurality of die pads;
C) forming a layer of solder on each of the copper pillars;
D) providing a substrate having a plurality of substrate pads, each of the plurality of substrate pads positioned on the substrate to align with a respective one of the copper pillars;
E) bringing the flip-chip device in proximity to the substrate until all the solder layers are in contact with respective substrate pads to form a device-substrate combination;
F) applying heat to the device-substrate combination to raise the temperature thereof until all of the solder melts; and
G) cooling the device-substrate combination to a temperature at which all of the solder solidifies;
wherein each substrate pad has an offset from a respective die pad at specific temperature, the offset for each of the substrate pads of the is determined as a function of the size of the flip-chip device, a difference between a solidification temperature of the solder and the specific temperature, a difference between a coefficient of thermal expansion of the flip-chip device and a coefficient of thermal expansion of the substrate, and a distance the respective die pad is with respect to the centroid.

22. The method of claim 21 wherein the offset of each one of the plurality of substrate pads is determined in accordance with the following relationship:
offset=DNPₘₐₓ×(CTE_{substrate}−CTE_{device})×(T_{solidification}−T)×(1−DNP_{pad}/DNPₘₐₓ)
where: offset is the amount of offset between a substrate pad and its respective die pad;
DNPₘₐₓ is a farthest distance on the device from the device centroid;
DNP_{pad} is a distance the die pad on the device is from the device centroid;
CTE_{substrate} and CTE_{device} are the coefficients of expansion of the substrate and flip-chip device, respectively; and
T_{solidification} and T are the solder solidification and the specific temperatures, respectively.

23. The method of claim 21 wherein each copper pillar has a height above a die pad and each of the solder layers has a height above a copper pillar, and a sum of the height of each copper pillar and its respective solder layer prior to step F) is between 5 microns and 130 microns.

24. The method of claim 21 wherein each copper pillar has a diameter of 80 microns or less and a sum of the height of each copper pillar and its respective solder layer prior to step F) is 80 microns or less.

25. The method of claim 21 wherein the flip-chip device comprises a material selected from the group consisting of silicon, gallium arsenide, indium phosphide, and a combination thereof, and the substrate is selected from the group consisting of glass-epoxy, polytetrafluoroethylene, ceramic, silicon, glass, a combination thereof, and a combination thereof.

26. The method of claim 21 further comprising the steps of:
H) forming, after step G), an underfill layer between the flip-chip device and the substrate.

27. The method of claim 26 further comprising the step of:
forming, after step H), an overmold on the flip-chip device and the substrate.

28. The method of claim 21 wherein the copper pillar is formed by the steps of:
depositing a photoresist onto the flip-chip device;
patterning, the photoresist to expose the plurality of die pads;
plating copper onto the exposed die pads; and
removing the photoresist.
